(19) United States
(12) Patent Application Publication
(10) Pub. No.: US 2008/0241999 A1
(43) Pub. Date: Oct. 2, 2008

(54) SEMICONDUCTOR DEVICE AND MANUFACTURING METHOD THEREFOR

(75) Inventor: Takashi Sato, Hamamatsu-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-Shi (JP)

(21) Appl. No.: 11/963,659

(22) Filed: Dec. 21, 2007

Related U.S. Application Data
(63) Continuation of application No. 10/321,568, filed on Dec. 18, 2002, now abandoned.

(30) Foreign Application Priority Data
Dec. 21, 2001 (JP) 2001-389014

(51) Int. Cl. H01L 21/50

(52) U.S. Cl. 438/113; 438/460; 257/E21.499

(57) ABSTRACT

A semiconductor device is manufactured by sealing a semiconductor chip, which is mounted on a prescribed support such as a lead frame, support bars, and a substrate connected with electrical wiring, in a package. Herein, individual information containing management information representing manufacturing conditions of semiconductor chips and test information representing results of testing of semiconductor chips is automatically recorded on a prescribed position of the prescribed support with respect to each of the semiconductor chips in synchronization with a die bonding process in response to the type of the package. That is, the individual information is recorded on exposed portions of outer leads, exposed portions of support bars, or the backside of the substrate, for example. This improves workability in reading and writing individual information without error, traceability to assure quality of semiconductor devices, and analysis of defects in semiconductor devices.

### CROSS REFERENCE TO RELATED APPLICATIONS

This application is based on and claims priority to U.S. patent application Ser. No. 10/321,568, filed Dec. 18, 2002, entitled SEMICONDUCTOR DEVICE AND MANUFACTURING METHOD THEREFOR, the entire disclosures of which is hereby incorporated by reference.

### BACKGROUND OF THE INVENTION

1. Field of the Invention

This invention relates to semiconductor devices and to manufacturing methods therefor, in which semiconductor chips are mounted on lead frames using die bonding techniques and are accompanied with readable marks or records representing individual information with regard to management and testing of semiconductor chips.

2. Description of the Related Art

In general, semiconductor devices are manufactured accompanied with readable marks or records representing individual information such as management information and test information, wherein the management information represent manufacturing conditions and evaluation results for use in quality control and defect analysis.

That is, in order to ensure the quality of products and to analyze defective products, semiconductor chips have records of manufacturing information, which store various data regarding manufacturing factories, model names, positional information on wafers, wafer lot numbers, histories of die bonding apparatuses, die bonding material data, and frame data, as well as evaluation information representing characteristics, test items, and test results.

For example, Japanese Unexamined Patent Publication No. 2000-228341 discloses an example of a semiconductor integrated circuit in which individual information such as management information and test information is recorded directly onto a semiconductor chip, which is separated from the wafer by dicing, in a memory circuit whose pattern is created by laser beams.

Japanese Unexamined Patent Publication No. 2001-28406 discloses an example of a semiconductor device in which individual information such as management information and test information regarding a semiconductor chip is recorded on a protective film for protecting the surface of the semiconductor chip, and a package for sealing the semiconductor chip, which is subjected to die bonding onto a lead frame.

In Japanese Unexamined Patent Publication No. 2000-228341 in which individual information such as management information and test information is directly recorded in the memory circuit fabricated in the semiconductor chip, it is impossible to directly read the individual information recorded on the semiconductor chip without establishing electrical connections between the memory circuit and an external access device. In addition, this example has a drawback in that the overall area of the semiconductor chip must be increased due to recording of the information.

To cope with the aforementioned drawback, Japanese Unexamined Patent Publication No. 2001-28406 teaches that the information once recorded on the protective film of the semiconductor chip is read out and is then recorded again on the package for sealing and enclosing the semiconductor chip.

Specifically, manufacturing information, which is produced in circuit forming processes of semiconductor devices, is originally recorded on the protective film of the semiconductor chip and is read out and stored in a database in advance. Then, the manufacturing information, which is read from the database, and evaluation information that is recorded in post-processing are both recorded on the package for sealing and enclosing the semiconductor chip. That is, the information once recorded on the protective film of the semiconductor chip is transferred to the package by way of the database, which is very troublesome. In addition, since the original information regarding the semiconductor chip is indirectly transferred onto the package, there is a possibility that the transferred information will not always match the original information.

Furthermore, the information is recorded on the ‘rough’ black surface of the package, which result in difficulty in reading the information using an optical reading device and the like. Therefore, it is necessary to further refine the techniques for recording information on such packages. That is, the aforementioned method may be difficult to practice in actual manufacturing and lacks general applicability in manufacturing.

### SUMMARY OF THE INVENTION

It is an object of this invention to provide a semiconductor device and a manufacturing method therefor, which provides readability allowing direct reading of individual information such as management information and test information, which are produced in the middle of the manufacturing processes. That is, this invention improves traceability for quality control and defect analysis, and workability in reading and writing operations, which ensure accurate recording of the individual information without error.

A semiconductor device of this invention is constituted by a semiconductor chip that is mounted on a prescribed support such as a lead frame, support bars, and a substrate connected with electrical wiring. In manufacture, there are provided individual information containing management information representing manufacturing conditions of semiconductor chips and test information representing results of testing of semiconductor chips. The individual information is automatically recorded on a prescribed position of the prescribed support with respect to each of the semiconductor chips in synchronization with a die bonding process.

In the case of a QFP package, for example, the individual information is recorded on the exposed portions of outer leads exposed from the package. In the case of a QFN package, the individual information is recorded on the exposed portions of the support bars for supporting and mounting the semiconductor chip. In the case of a BGA package, the individual information is recorded on the backside of the substrate on which the semiconductor chip is mounted.

### BRIEF DESCRIPTION OF THE DRAWINGS

These and other objects, aspects, and embodiments of the present invention will be described in more detail with reference to the following drawings, in which:

FIG. 1A is a plan view showing a semiconductor wafer on which a prescribed number of semiconductor chips are arranged in a prescribed coordinate system whose horizontal direction is defined in accordance with an orientation flat;

FIG. 1B is a plan view showing an arrangement of semiconductor chips, which are cut out from the semiconductor wafer by dicing and are bonded onto a lead frame having outer leads;

FIG. 2 is a fragmentary perspective view showing a selected portion of a semiconductor device having records of individual information in accordance with a first embodiment of the invention;

FIG. 3A is a backside view of a QFN package enclosing a semiconductor chip and having records of individual information on exposed portions of support bars in accordance with a second embodiment of the invention;

FIG. 3B is a cross sectional view taken along the line A-A′ in FIG. 3A;

FIG. 4A is a backside view of a BGA package enclosing a semiconductor chip and having records of individual information on exterior surfaces in accordance with a third embodiment of the invention;

FIG. 4B is a cross sectional view taken along the line B-B′ in FIG. 4A;

FIG. 5 is a schematic diagram showing manufacturing processes of semiconductor devices in accordance with the invention; and

FIG. 6 is a table showing examples of marks of individual information for use in semiconductor devices.

### DESCRIPTION OF THE PREFERRED EMBODIMENTS

This invention will be described in further detail by way of examples with reference to the accompanying drawings.

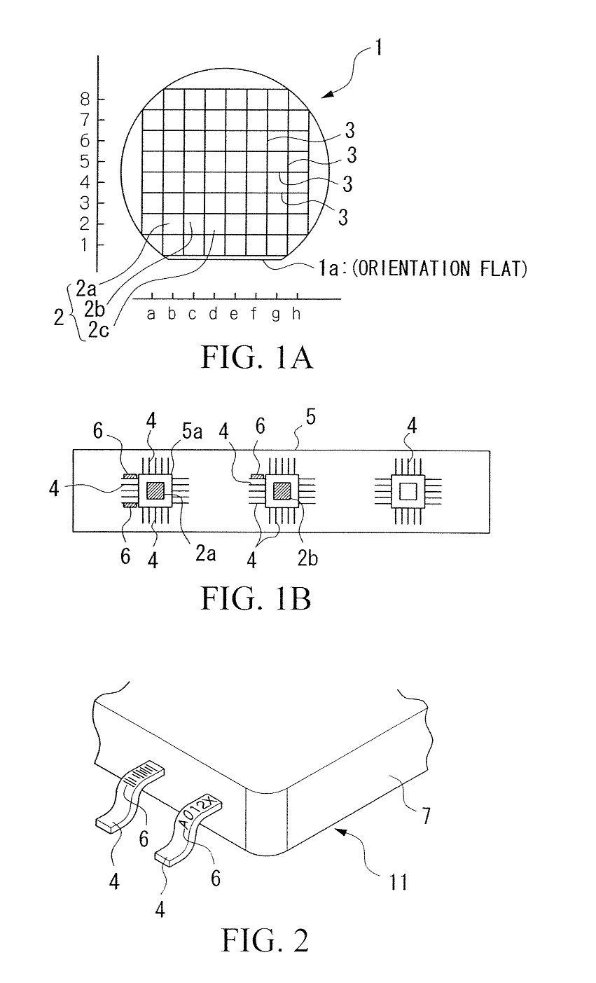

Now, the overall chip structures of semiconductor devices will be described in accordance with the first embodiment of the invention with reference to FIGS. 1A and 1B. FIG. 1A shows a silicon wafer 1 before wafer dicing, on which the prescribed number of square semiconductor chips 2 are formed using lithography and the like. Specifically, semiconductor chips 2a, 2b, 2c, . . . are regularly formed in vertical and horizontal directions on the silicon wafer 1. The semiconductor chips 2 collectively formed on the silicone wafer 1 are each cut along dicing lines 3 in post-processing, so that they are divided into square-shaped chips.

Then, the divided semiconductor chips 2a, 2b, 2c, . . . are arranged on a lead frame 5 having frame leads (or outer leads) 4 shown in FIG. 1B. Die bonding materials are used to bond and fix them to the lead frame 5 at respective positions.

The present embodiment is characterized by recording (or printing) individual information 6 at prescribed positions on the lead frame 5, wherein the individual information 6 contains management information, which represents manufacturing conditions of semiconductor chips 2a, 2b, 2c, . . . respectively bonded onto the lead frame 5, and test information representing their characteristics.

In particular, it is preferable to record the individual information 6 on prescribed frame leads 4, to which the semiconductor chips 2a, 2b, 2c, . . . are each bonded. Herein, the individual information 6 is not necessarily recorded on specific leads 4, whereas large amounts of information can be recorded over multiple leads 4.

The aforementioned semiconductor chips 2, which are bonded onto the lead frame 5 and accompanied with records (or prints) of the individual information 6 at the prescribed leads 4, are sealed and enclosed within packages, each of which is then cut and isolated from the lead frame 5 to produce a complete product of a semiconductor device. FIG. 2 shows a selected corner portion of a package 7 that seals and encloses a semiconductor chip 2a connected with frame leads 4, some of which have records (or prints) of individual information 6. Herein, the individual information 6 is recorded on shoulder portions of the outer leads 4, which are separated from the lead frame 5.

As described above, the individual information 6 contains management information and test information, wherein the management information represents the manufacturing factory, manufacturing year and date, silicon wafer lot number, positional information on the silicon wafer 1, history of the die bonding apparatus, and die bonding material data, while the test information represents the chip characteristics, test number, test data, and frame data with respect to each semiconductor chip, for example.

In the individual information 6, the positional information can be specified, for example, with respect to the semiconductor chip 2a on the silicon wafer 1 shown in FIG. 1A. In general, formation of patterns of semiconductor chips is performed with respect to an orientation flat 1a, representing one of the crystal axis directions on the plane of the wafer 1, and its perpendicular direction. That is, a first coordinate axis is set in parallel with the orientation flat 1a, and a second coordinate axis is set perpendicular to the orientation flat 1a within the plane of the wafer 1. Using such a coordinate system shown in FIG. 1A, the positional information on the silicon wafer 1 is determined with respect to each of the semiconductor chips 2a, 2b, 2c, . . . .

The other items of the management information such as the manufacturing factory, manufacturing year and date, silicon wafer lot number, history of the die bonding apparatus, and die bonding material data are always specified during manufacturing processes for formation of semiconductor chips. In addition, items of the test information such as chip characteristics are specified by performing measurement on semiconductor chips using a prescribed test apparatus.

The aforementioned first embodiment is applied to semiconductor devices, in which semiconductor chips 2 are bonded and fixed to a typical type of the lead frame 5 having the outer leads 4 on the four sides, which correspond to QFP (Quad Flat Pack) packages.

This invention is not necessarily applied to QFP packages and is applicable to other types of packages having no outer lead terminals, namely, QFN packages (having no lead pins on four sides), CSN packages (namely, chip size or scale packaging), and BGA (Ball Grid Array) packages, which will be described as other embodiments in which individual information is recorded at specific positions other than the outer leads 4.

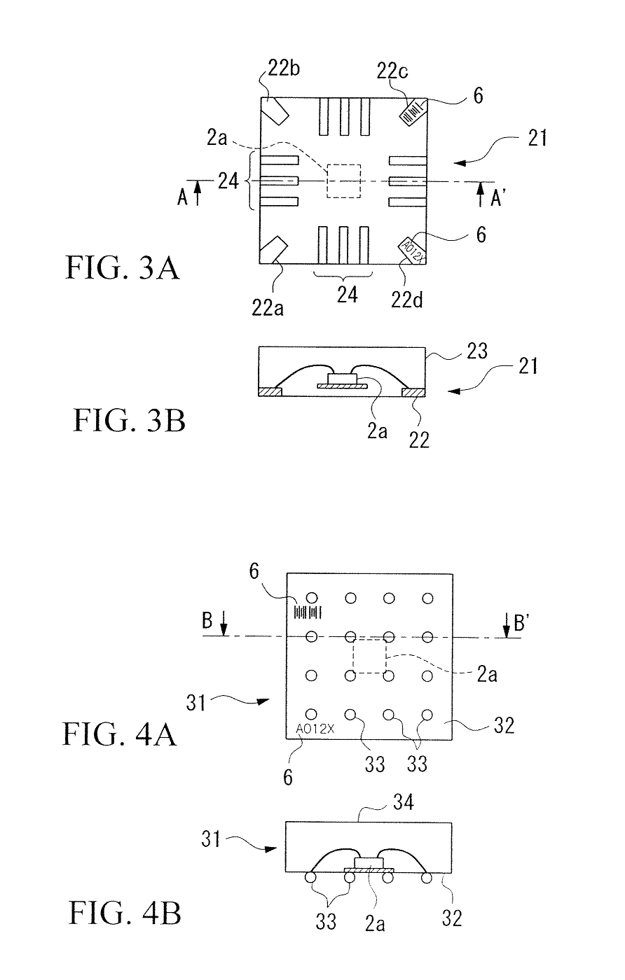

With reference to FIGS. 3A and 3B, the second embodiment will be described with respect to a semiconductor device 21 encapsulated in a QFN package. FIG. 3A is a backside view of the semiconductor device 21, and FIG. 3B is a cross sectional view taken along the line A-A′ in FIG. 3A.

A semiconductor chip 2 (2a) is supported by four support bars 22 (22a-22d) and is enclosed in a package 23, wherein the support bars 22 are partially exposed at the backside of the package 23. The individual information 6 containing the management information and test information is recorded on the support bars 22, wherein FIG. 3B shows that the individual information 6 is recorded on the support bars 22c and 22d. That is, the individual information 6 is recorded on the exterior surface or surfaces (e.g., backside and/or selected side) of the package 23 that a human operator can visually recognize as necessary. Specifically, the individual information 6 is securely recorded on the exposed portions of the support bars 22. Reference numeral 24 designate leads that are connected with electrode pads.

With reference to FIGS. 4A and 4B, the third embodiment will be described with respect to a semiconductor device 31 encapsulated in a BGA package. FIG. 4A is a backside view of the package, and FIG. 4B is a cross sectional view taken along the line B-B′ in FIG. 4A.

In the semiconductor device 31 enclosed in the BGA package, a semiconductor chip 2 (2a) is fixed onto the surface of a substrate 31 whose backside has printed wiring. In addition, metal bumps (or balls) 33 corresponding to external terminals are arranged in a grid form on the backside of the substrate 32.

The individual information 6, which contain the management information and test information with regard to the semiconductor chip 2a fixed onto the surface of the substrate 32, is recorded on the backside and/or selected side of the substrate 32. That is, the individual information 6 is securely recorded on the exterior surface or surfaces of the package that a human operator can visually recognize as necessary. Reference numeral 34 designates the package.

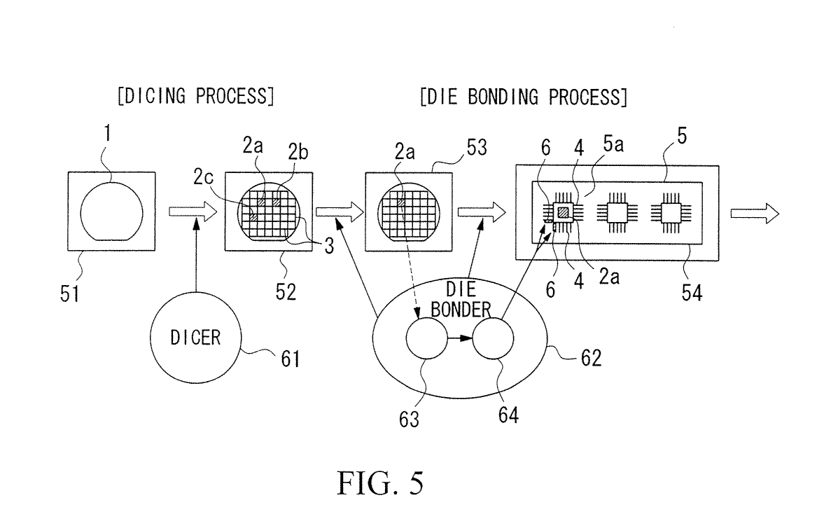

Next, a manufacturing method for the aforementioned semiconductor device will be described with reference to FIG. 5.

The silicon wafer 1 on which numerous semiconductor chips 2a, 2b, 2c, . . . are formed is subjected to a dicing process in which it is cut and divided along dicing lines 3 by a dicer 61, so that the semiconductor chips 2a, 2b, 2c, . . . are individually separated from each other.

Then, the individual semiconductor chips 2a, 2b, 2c, . . . are each subjected to a die bonding process. That is, the semiconductor chip 2a, for example, is picked up by a die bonder 62 and is transported onto the lead frame 5, so that the semiconductor chip 2a is bonded and fixed to the lead frame 5 at a prescribed position.

When picked up by the die bonder 62, the semiconductor chip 2a is placed under an information reader 63 such as a barcode reader or a scanner, which reads the individual information 6 such as the management information and test information recorded at prescribed positions of the substrate or support bars with respect to the semiconductor chip 2a. Then, the read individual information 6 is sent to a recorder 64, which in turn records it on the frame lead (or outer lead) 4 arranged at a prescribed position 5a of the lead frame 5 after the die bonder 62 bonds and fixes the semiconductor chip 2a to the lead frame 5 at the prescribed position 5a.

In the above, operations to read the individual information 6 of the semiconductor chip 2a and to record it on the lead frame 5 are performed in synchronization with the aforementioned die bonding process. Therefore, both the reader 63 and recorder 64 are incorporated into the die bonder 62 in such a way that they can operate in accordance with a prescribed sequence in synchronization with the operation of the die bonder 62. Thus, it is possible to efficiently perform the aforementioned operations.

The aforementioned manufacturing process is described with respect to the QFP-type semiconductor device 11 in which the individual semiconductor chip 2a is bonded to the lead frame 5 in accordance with the first embodiment. In the manufacture of the QFN-type semiconductor device 21 shown in FIGS. 3A and 3B in which the individual semiconductor chip 2a is fixed in position by the support bars 2 in accordance with the second embodiment, the individual information 6 is recorded on the support bars 22 when the semiconductor chip 2a is fixed to the support bars 22 in the die bonding process.

In the manufacture of the BGA-type semiconductor device 31 shown in FIGS. 4A and 4B in which the individual semiconductor chip 2a is fixed to the substrate 32 in accordance with the third embodiment, the individual information 6 is recorded on the backside and/or selected side of the substrate 32 when the semiconductor chip 2a is fixed to the substrate 32 in the die bonding process.

A laser apparatus is used to record the individual information 6 on prescribed positions of semiconductor devices by using laser beams. For example, it is possible to use the following laser apparatuses.
(a) Solid-state laser: YAG (Neodymium-doped yttrium-aluminum garnet) laser or semiconductor laser.
(b) Gas laser: helium-neon (He—Ne) laser, carbon dioxide (CO₂) laser, KrF excimer laser, Ar ion laser, and ultraviolet laser.
(c) Liquid laser: dye laser.

The YAG laser operates under prescribed conditions in which the unit heating value ranges from 2 mJ/cm² to 6 mJ/cm², the used wavelength is set to 532 nm, and the peak power ranges from 0.5 Mw to 0.88 Mw, for example.

The KrF excimer laser operates in prescribed conditions where the unit heating value ranges from 10 J/cm² to 15 J/cm², and the wavelength is set to 248 nm, for example.

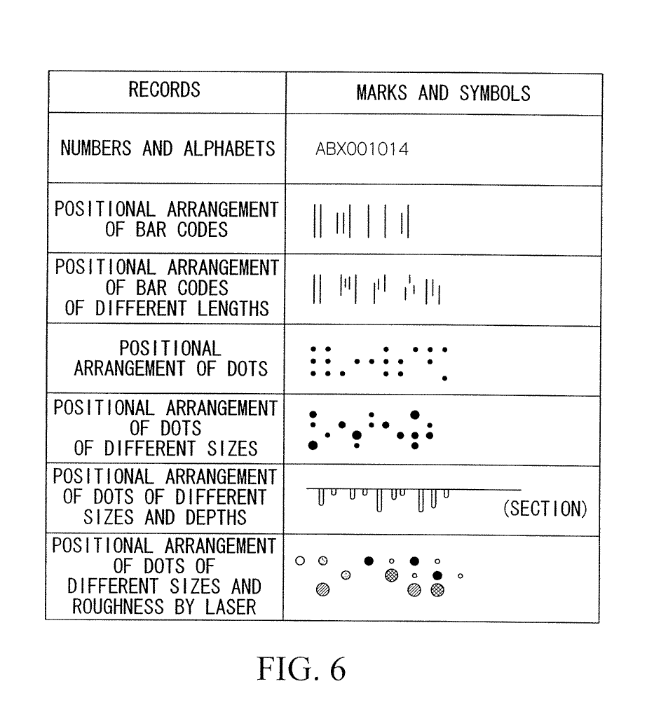

Various symbols and identification marks can be used for the individual information 6 recorded on the semiconductor device shown in the aforementioned figures. In addition, it is possible to use other symbols and identification marks listed in the table shown in FIG. 6.

The individual information 6 is stamped onto the prescribed surface of the frame lead(s) 4 in which shallow hollows are formed in order to enable optical reading even though solder reflow occurs on the surface of the frame leads 4.

As described heretofore, this invention has a variety of effects and technical features, which will be described below.
(1) Semiconductor devices of this invention are manufactured in such a way that individual information containing management information representing manufacturing conditions of semiconductor chips and test information representing results of testing of characteristics of semiconductor chips is recorded on prescribed supports such as lead frames onto which semiconductor chips are bonded and fixed, support bars for supporting semiconductor chips, and exterior surfaces of substrates for mounting semiconductor chips connected with electrical wiring. This allows human operators or inspection apparatuses to read information regarding semiconductor devices including information regarding processing of wafers without requiring destruction of sealed containers such as packages. Therefore, it is possible for human operators to promptly cope with problems by using the individual information, which may be necessary for analysis of causes of defects in semiconductor devices. That is, it is possible to noticeably improve traceability in analyzing causes of defects in semiconductor chips.
(2) The individual information is recorded (or printed) on metal parts (or supports) such as lead frames and support bars, which have planar surfaces producing high reflectivity against light beams and the like. Therefore, it is possible to easily and reliably perform optical reading with respect to individual information of semiconductor devices. That is, it is possible to use normal optical detectors for use in inspection of semiconductor devices, which may generally be used in manufacture and inspection of semiconductor devices. In addition, this provides a relatively great degree of readability in reading individual information of semiconductor devices, regardless of reflow of solders occurring on surfaces of leads in post-processing.
(3) Individual information containing management information and test information regarding individual semiconductor chips is recorded on lead frames, support bars, or substrates in die bonding processes, wherein the individual information is directly read from the individual semiconductor chip and is then subjected to recording. This assures accurate recording individually with respect to semiconductor devices in conformity with individual information originally recorded in semiconductor chips. This allows human operators to promptly read individual information of semiconductor devices without error, so that human operators will be able to adequately cope with causes of defects in semiconductor devices. In addition, reading and writing operations of individual information of semiconductor chips can be automated in synchronization with die bonding processes. Thus, it is possible to remarkably improve workability and efficiency of manufacture and inspection of semiconductor devices.

As this invention may be embodied in several forms without departing from the spirit or essential characteristics thereof, the present embodiments are therefore illustrative and not restrictive, since the scope of the invention is defined by the appended claims rather than by the description preceding them, and all changes that fall within metes and bounds of the claims, or equivalents of such metes and bounds are therefore intended to be embraced by the claims.

What is claimed is:

1. A manufacturing method of a semiconductor device comprising the steps of:
performing a dicing process in which a semiconductor wafer, on which plural semiconductor chips arc formed, is subjected to dicing, so that the plural semiconductor chips are divided and separated from each other;
performing a die bonding process using a die bonder in which each of the semiconductor chips is individually bonded and fixed to a prescribed support;
reading individual information with respect to each of the semiconductor chips by the die bonder in synchronization with the die bonding process; and
recording the individual information on a prescribed position of the prescribed support, the recording being performed by the die bonder in synchronization with the die bonding process.

2. The manufacturing method of a semiconductor device according to claim 1, wherein the individual information contains management information representing manufacturing conditions of the semiconductor chip and test information representing results of testing of the semiconductor chip.

3. The manufacturing method of a semiconductor device according to claim 1, wherein the prescribed support is selected from among a lead frame, support bars, and a substrate.

4. The manufacturing method of a semiconductor device according to claim 1, wherein the prescribed support corresponds to a lead frame, so that the individual information is recorded on at least one outer lead.

5. The manufacturing method of a semiconductor device according to claim 1, wherein the prescribed support corresponds to at least one support bar, so that the individual information is recorded on the at least one support bar.

6. The manufacturing method of a semiconductor device according to claim 1, wherein the prescribed support corresponds to a substrate having a surface on which the semiconductor chip is bonded, so that the individual information is recorded on a backside of the substrate.

7. The manufacturing method of a semiconductor device according to claim 1, wherein the individual information is positional information representing a position of a respective semiconductor chip with respect to the semiconductor wafer.

8. A manufacturing method of a semiconductor device comprising the steps of:
performing a dicing process in which a semiconductor wafer, on which plural semiconductor chips are formed, is subjected to dicing, so that the plural semiconductor chips are divided and separated from each other;
performing a die bonding process by a die bonder in which each of the semiconductor chips is individually bonded and fixed to a prescribed support;
reading individual information with respect to each of the semiconductor chips by the die bonder in synchronization with the die bonding process;
reading positional information representing a position of the respective semiconductor chips with respect to the wafer when each semiconductor chip is picked up by the die bonder in synchronization with the die bonding process; and
recording the individual information and the positional information at a prescribed position of the prescribed support, the recording being performed by the die bonder in synchronization with the die bonding process.

9. A manufacturing method of a semiconductor device comprising the steps of:
performing a dicing process in which a semiconductor wafer, on which plural semiconductor chips are formed, is subjected to dicing, so that the plural semiconductor chips are divided and separated from each other;
performing a die bonding process in which each of the semiconductor chips is individually bonded and fixed to a prescribed support;
reading individual information with respect to each of the semiconductor chips by the die bonder in synchronization with the die bonding process;
reading positional information representing a position of the respective semiconductor chips with respect to the wafer when each semiconductor chip is picked up by the die bonder in synchronization with the die bonding process; and
recording the individual information on a prescribed position of the prescribed support to be exposed at a backside of a package, the recording being performed by the die bonder in synchronization with the die bonding process.
